(19) United States
(12) Patent Application Publication
(10) Pub. No.: US 2017/0191879 A1
(43) Pub. Date: Jul. 6, 2017

(54) TEMPERATURE SENSORS WITH INTEGRATED SENSING COMPONENTS

(71) Applicant: Applied Electronic Materials, LLC, Fort Wayne, IN (US)

(72) Inventor: Tom Martin, Fort Wayne, IN (US)

(21) Appl. No.: 15/393,657

(22) Filed: Dec. 29, 2016

Related U.S. Application Data
(60) Provisional application No. 62/272,801, filed on Dec. 30, 2015.

(51) Int. Cl. G01K 7/02; H05K 1/09; H05K 3/12; H05K 3/00; G01K 7/16; H05K 3/22

(52) U.S. Cl. CPC G01K 7/02; G01K 7/16; H05K 3/22; H05K 3/1291; H05K 3/0014; H05K 1/09; H05K 2201/10151; H05K 2203/11

(57) ABSTRACT

Temperature sensors and, in particular, temperature sensors of the thermocouple (TC) and resistance temperature detector (RTD) types. The temperature sensors are manufactured by sequential deposition of insulating and temperature sensor layers onto a substrate via thick film techniques. The temperature sensor layer includes a temperature sensor element, which may be configured as a conductor pair forming a thermocouple junction or as a resistance temperature detector filament. The substrate may optionally be roll formed after thick film processing from a flat, manufacturing configuration into a tube shaped use configuration, in which the layers and temperature sensor elements are disposed within an interior of the device. The conductors or filaments of temperature sensor elements may extend along the length of the sensor substrate to minimize the number of electrical connections present, thereby easing manufacture and decreasing points of potential operational failure.

### CROSS REFERENCE TO RELATED APPLICATIONS

This application claims the benefit under Title 35, U.S.C. §119(e) of U.S. Provisional Patent Application Ser. No. 62/272,801, entitled TEMPERATURE SENSORS WITH INTEGRATED SENSING COMPONENTS, filed on Dec. 30, 2015, the disclosure of which is expressly incorporated herein by reference.

### BACKGROUND

1. Field of the Disclosure

The present disclosure relates to temperature sensors and, in particular, to temperature sensors of the thermocouple (TC) and resistance temperature detector (RTD) types.

2. Description of the Related Art

Temperatures sensors, detectors, or probes are used in many industrial and consumer applications to detect a temperature within an environment, typically an environment with an elevated temperature such as within a furnace or a chemical reaction chamber, or an exhaust temperature within an exhaust conduit of a vehicle, for example.

One known type of temperature sensor is of the thermocouple (TC) type, which is based on the use of two different conductors which contact one another to form an electrical thermocouple junction, with the thermocouple producing a temperature—dependent voltage as a result of the thermoelectric effect. The detected voltage is interpreted to measure a temperature. One disadvantage with thermocouple (TC) type sensors is that the conductors forming the thermocouple junction are typically very fragile, and therefore are often placed within an enclosure or protective sheath for protection in order to minimize chances of mechanical failure.

Another type of temperature sensor is of the resistance temperature detector (RTD) type, which employs a thin filament of a pure metal such as platinum, nickel, or copper, for example. RTD sensors measure a temperature by correlating the resistance of the filament with a temperature. Many RTD sensors include a filament in the form of length of fine coiled wire wrapped around a ceramic or glass core, or a serpentine pattern of a fine wire supported by a substrate. One advantage of RTD sensors is that if a pure metal is used, the metal has a highly predictable change in resistance that may be correlated to temperature changes with high accuracy. Similar to thermocouple (TC) type sensors, one disadvantage with RTD sensors is that the RTD element itself is typically very fragile, and is typically also placed within an enclosure or protective sheath and/or embedded in a cement material for protection.

Further disadvantages with known temperature sensors of both the TC and RTD type described above are illustrated below in FIG. 1 in the context of a known RTD temperature sensor 20. The RTD temperature sensor 20 includes a metallic filament 22 supported on a substrate plate 24. A cover 26 covers a distal end of sensor 20 which is exposed to an operational environment, such as an elevated temperature environment and/or harsh environmental conditions on an operational side 28 of a housing or fitting structure 30 in which sensor 20 is mounted. A filler material 32, such as a mineral or refractory material, may optionally be disposed within cover 26 to surround and protect the filament 22. Filament 22 is connected to leads 34 of a mineral insulated (MI) cable 36, with leads 34 further connected to primary leads 38 of an electrical connector structure 40 which is, in turn, ultimately connected to a control device such as computer or processor (not shown), by which the signals can be measured or processed.

Disadvantageously, and similar to the conductors of a TC sensor, the filament 22 of the RTD sensor is quite fragile and may be prone to mechanical failure. Further, a number of electrical connections are needed between various materials of differing construction within the sensor 20 in order to convey signals from the filament 22 to the control device where the signals are ultimately measured or processed. For example, in the construction of the exemplary sensor 20 shown in FIG. 1, a first connection between dissimilar materials is provided between the filament 22 and the leads 34 of the MI cable 36, a second connection is provided between the MI cable leads 34 and the primary leads 38, and so on. Each connection point adds an additional manufacturing step as well as a point of potential connective failure to the construction of the sensor 20.

What is needed is a temperature sensor construction and assembly method which is an improvement over the foregoing.

### SUMMARY

The present disclosure provides temperature sensors and, in particular, temperature sensors of the thermocouple (TC) and resistance temperature detector (RTD) types. The temperature sensors are manufactured by sequential deposition of insulating and temperature sensor layers onto a substrate via thick film techniques. The temperature sensor layer includes a temperature sensor element, which may be configured as a conductor pair forming a thermocouple junction or as a resistance temperature detector filament. The substrate may optionally be roll formed after thick film processing from a flat, manufacturing configuration into a tube shaped use configuration, in which the layers and temperature sensor elements are disposed within an interior of the device. The conductors or filaments of temperature sensor elements may extend along the length of the sensor substrate to minimize the number of electrical connections present, thereby easing manufacture and decreasing points of potential operational failure.

In one form thereof, the present invention provides a temperature sensor, including an elongate metallic substrate having a deposition surface and opposite distal and proximal ends, said distal end adapted to be exposed to a high temperature environment; an insulating layer deposited on at least a portion of said deposition surface of said substrate; a temperature sensor layer deposited on said insulating layer, said temperature sensor layer including a temperature sensor element at said distal end of said substrate, said temperature sensor element in the form of a thermocouple junction including first and second conductors made of differing metallic materials, respective portions of said first and second conductors directly connected to one another; and a plurality of elongate conductors extending from said temperature sensor element to said proximal end of said substrate.

In another form thereof, the present invention provides a method of manufacturing a temperature sensor, including the following steps: providing an elongate substrate having distal and proximal ends; applying an insulating material onto a surface of the substrate via a thick film deposition process; heat curing the insulating material to form an insulating layer; applying a first metallic composition; applying a second metallic composition with at least a portion of the second metallic composition applied over and in contact with the first metallic composition; and heat curing the first and second metallic compositions simultaneously to form first and second conductors with at least a portion of the second conductor directly contacting the first conductor to form a thermocouple junction.

In a further form thereof, the present invention provides a method of manufacturing a temperature sensor, including the following steps: providing a ceramic tape having opposite first and second sides; applying a first metallic composition to the first side of the ceramic tape via a thick film deposition process; applying a second metallic composition to the first side of the ceramic tape via a thick film deposition process with at least a portion of the second metallic composition applied over and in contact with the first metallic composition; and heat curing the ceramic tape and the temperature sensor material to heat cure the first and second metallic compositions simultaneously to form first and second conductors with at least a portion of the second conductor directly contacting the first conductor to form a thermocouple junction.

### BRIEF DESCRIPTION OF THE DRAWINGS

The above-mentioned and other features of the disclosure, and the manner of attaining them, will become more apparent and will be better understood by reference to the following description of embodiments of the disclosure taken in conjunction with the accompanying drawings, wherein:

FIG. 1 is a sectional view of a known RTD type temperature sensor;

FIG. 2 is a perspective view of a TC type temperature sensor of the present disclosure, shown in a manufacturing configuration;

FIG. 3A is a sectional view taken along line 3A-3A of FIG. 2;

FIG. 3B is an enlarged fragmentary view of a portion of FIG. 3A;

FIG. 4 is an exploded perspective view of a temperature sensor showing insulation and temperature sensor layers in connection with a printed ceramic tape which is laminated onto a substrate, though in another embodiment, the temperature sensor may lack the substrate and may take the form of a freestanding body including only the ceramic tape and temperature sensor layer, wherein the presence (or lack) of the substrate is illustrated by the combination bracket shown in dashed lines;

FIG. 5 is a perspective, partially cut away view of the TC type temperature sensor of FIGS. 2 and 4, shown in a use configuration;

FIG. 6 is a partial perspective view of another TC type temperature sensor of the present disclosure, shown in a manufacturing configuration;

FIG. 7A is a perspective view of an RTD type temperature sensor of the present disclosure, shown in a manufacturing configuration;

FIG. 7B is an enlarged fragmentary view of a portion of FIG. 7A;

FIG. 8 is a sectional view taken along line 8-8 of FIG. 7A;

FIG. 9 is a perspective, partially cut away view of the TC type temperature sensor of FIG. 7A, shown in a use configuration;

FIG. 10 is a partial perspective view of another TC type temperature sensor of the present disclosure, shown in a manufacturing configuration;

FIG. 11 is a perspective view of a TC or RTD type temperature sensor in a use environment;

FIG. 12 is a perspective view of a TC type temperature sensor of a further embodiment, illustrating how portions of the substrate and sensor body may be disposed at an angle with respect to one another;

FIG. 13A is a sectional view of a TC or RTD type temperature sensor, showing the substrate and sensor body is a circular cross-sectional configuration;

FIG. 13B is a sectional view of a TC or RTD type temperature sensor, showing the substrate and sensor body is an ovoid cross-sectional configuration; and

FIG. 13C is a sectional view of a TC or RTD type temperature sensor, showing the substrate and sensor body is a triangular cross-sectional configuration.

Corresponding reference characters indicate corresponding parts throughout the several views. The exemplifications set out herein illustrate embodiments of the disclosure and such exemplifications are not to be construed as limiting the scope of the invention in any manner.

### DETAILED DESCRIPTION

The present disclosure is described below in detail in connection with temperature sensors of the thermocouple (TC) and resistance temperature detector (RTD) type, though could also be applicable to temperature sensors of other constructions. In each embodiment, materials in layer form are deposited onto a substrate via thick film techniques such as screen printing, for example, followed by heat curing as described in detail below.

I. Thermocouple (TC) Type Temperature Sensors

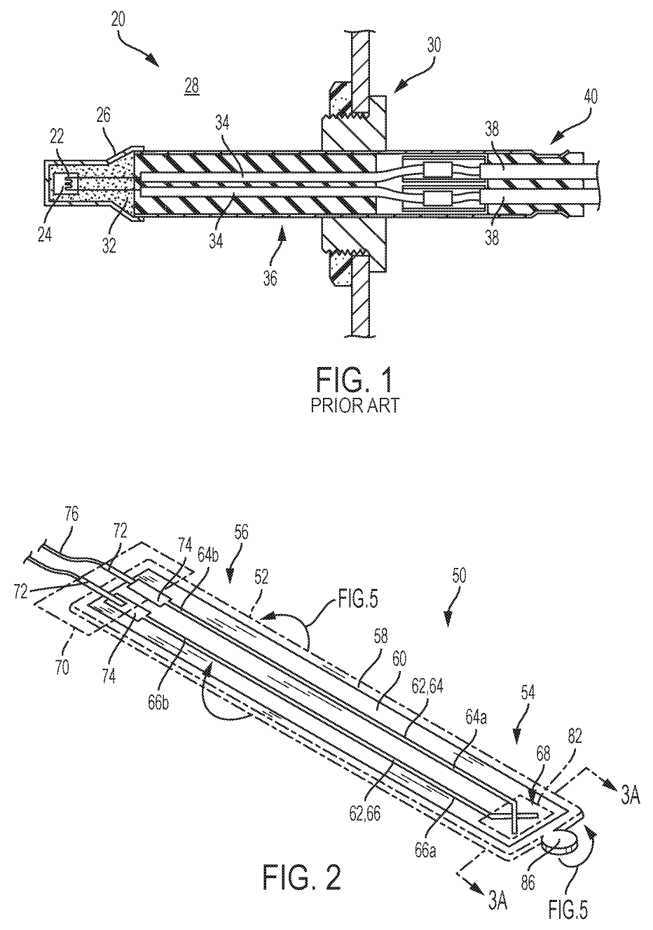

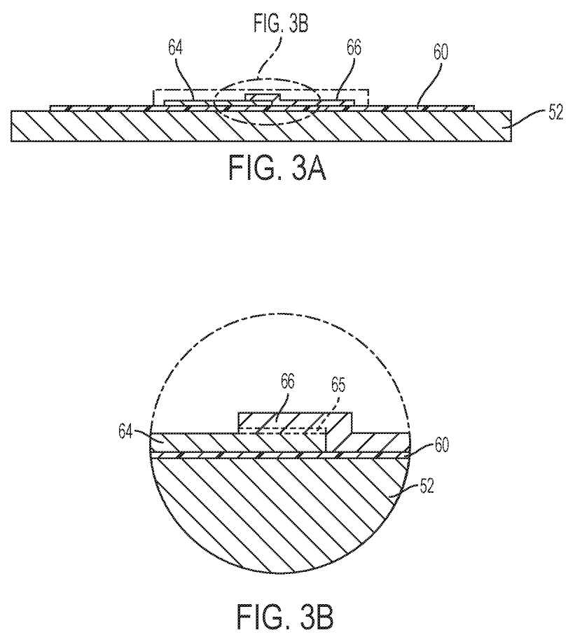

Referring to FIGS. 2 and 3A, a TC type temperature sensor 50 is shown, which includes an elongate substrate 52 made of a highly temperature resistant material such as stainless steel, for example. Substrate 52 includes a distal end 54, a proximal end 56, and an exposed deposition surface 58, typically the upper surface of substrate 52, on which a temperature sensor structure is directly deposited via a thick film application method, as described further below. The boundaries of substrate 52 are shown in dashed lines to indicate that they are variable, for example, substrate 52 may have a width beyond the extent of the temperature sensor structure which is sufficient for forming substrate 52 into use configurations of various cross-sectional shapes, as described in further detail below.

If substrate 52 is made of stainless steel, the deposition surface 58 is the exposed surface of the stainless steel. Other suitable materials for substrate include nickel-chromium alloys, available under the trade name Inconel, which are oxidation and corrosion resistant and thereby well suited for service in extreme environments subjected to pressure and/or heat. The length of substrate 52 may vary, though will typically be as little as 0.5 inches, 1 inch, or 3 inches or as great as 5 inches, 7 inches or 10 inches, for example, or may be with any length range between and pair of the foregoing values.

A dielectric or electrically insulating layer 60 is deposited directly onto deposition surface 58 of substrate 52 via a thick film technique such as screen printing. The composition of the insulating layer 60 may be provided in the form of a viscous liquid or paste which generally includes at least one polymer resin, inorganic particles, a glass phase, and at least one organic carrier liquid or solvent.

Generally, the insulating layer 60 functions to electrically insulate the material of substrate 52 from a temperature sensor layer, described below, which is subsequently deposited on insulating layer 60. In the pre-cured composition of insulating layer 60, the polymeric resin provides a binder or carrier matrix for the inorganic particles, and also provides adhesion of the composition to the underlying substrate 52 prior to the heat cure step in which the polymeric resin is removed. The inorganic particles form the bulk material of insulating layer 60. The organic carrier liquid provides a removable carrier medium to facilitate application of insulating layer 60 prior to heat cure, and is removed upon heat cure. The pre-cured composition of insulating layer 60 may also include other additives, such as surfactants, stabilizer, dispersants, as well as one or more thixotropic agents such as hydrogenated castor oil, for example, to increase the viscosity as necessary in order to form a paste.

The polymer resin may be an epoxy resin, ethyl cellulose, ethyl hydroxyethyl cellulose, wood rosin, phenolic resins, polymethacrylates of lower alcohols, or mixtures of the foregoing.

The inorganic particles may be oxides such as aluminum oxide, calcium oxide, nickel oxide, silicon dioxide, or zinc oxide, for example, and/or other inorganic particles such as aluminum nitride, beryllium oxide, and may have a particle size of 5 microns or less, and up to 10 microns, for example. Advantageously, the use of dielectric inorganic materials in insulating layer 60 which are chemically similar to the underlying substrate 52 may provide a favorable coefficient of thermal expansion (CTE) match with the substrate 52 for enhanced thermal cycling durability and consequent physical longevity.

The inorganic portion of the composition of insulating layer 60 may also include a glass phase, such as a borosilicate glass frit, which provides a matrix for the inorganic particles, facilitates sintering during the heat cure step at temperatures below the melting point of the substrate 52, and also provides adhesion of the composition of insulating layer 60 to the underlying substrate 52 after the heat cure step.

Suitable solvents may include relatively high boiling solvents having a boiling point of 125° C. or greater, which evolve at a slower rate than relatively lower boiling point solvents in order to provide a sufficiently long dwell time of the composition on the screen during the printing process. Examples of relatively high boiling point solvents include ethylene glycol, propylene glycol, di(ethylene)glycol, tri(ethylene)glycol, tetra(ethylene)glycol, penta(ethylene)glycol, di(propylene)glycol, hexa(ethylene)glycol, di(propylene)glycol methyl ether, as well as alkyl ethers of any of the foregoing and mixtures of the foregoing.

In the composition of insulation layer 60, the inorganic content is typically as low as 45 wt. %, 50 wt. %, or 55 wt. % and as great as 70 wt. %, 75 wt. %, or 80 wt. % of the total composition, or may be present within any range defined between any two of the foregoing values, and the organic content is typically as low as 20 wt. %, 25 wt. %, or 30 wt. %, or as great as 45 wt. %, 50 wt. % or 55 wt. % of the total composition, or may be present within any range defined between any two of the foregoing values. Of the inorganic content of the composition, the glass phase is typically present in an amount as low as 15 wt. %, 20 wt. %, or 25 wt. % and as great as 45 wt. %, 50 wt. %, or 55 wt. % of the total inorganic content, or may be present within any range defined between any two of the foregoing values, with the inorganic particles comprising the balance of the inorganic content of the composition. The solvent typically comprises as low as 65 wt. %, 70 wt. %, or 75 wt. % and as great as 85 wt. %, 90 wt. %, or 95 wt. % of the total organic content of the composition, or may be present within any range defined between any two of the foregoing values.

The composition of insulating layer 60 may be applied via a screen printing process through a screen or stencil (not shown) directly onto deposition surface 58 of substrate 52, optionally followed by an initial drying step, either at ambient or elevated temperature, in which some of the volatile components of the composition are evaporated. In a subsequent step after initial application followed by optional drying, insulating layer 60 may be heat cured in a furnace, such as a belt furnace, by heating insulating layer 60 to a desired elevated curing temperature to drive off any remaining volatile components, leaving the final layer in cured, solid form. The curing temperature will typically be greater than 800° C., and below the melting point of the substrate.

As desired, the foregoing process steps may be repeated to sequentially build insulating layer 60 to a desired final applied thickness. In one embodiment, insulating layer 60, after completion of a desired number of the foregoing application, drying, and heat curing steps, may be applied to a total film thickness of as little as 5 microns, 10 microns, 25 microns, or 50 microns, or as great as 100 microns, 250 microns, or 500 microns, or within any range defined between any two of the foregoing values.

After insulating layer 60 is applied and cured, a temperature sensor layer 62, which includes one or more temperature sensor elements as described below, may be deposited directly onto insulating layer 60 via similar thick film techniques. The temperature sensor layer 62 may be provided in the form of a viscous liquid or paste which generally includes conductive metal particles, at least one polymeric resin, and at least one organic carrier liquid or solvent. The composition forming temperature sensor layer 62 may also include a glass phase or metal oxide particles to promote adhesion of temperature sensor layer 62 to the underlying insulating layer 60.

Referring additionally to FIG. 3A, temperature sensor layer 62 includes two elongate conductors 64 and 66 which extend from distal end 54 to proximal end 56 of substrate 52 and are directly connected to one another to form a sensor element in the form of a thermocouple (TC) junction 68. The type of TC junction 68 and the composition of conductors 64 and 66 may vary. In one exemplary embodiment, TC junction 68 is a Type N junction, with one conductor 64 made of a Ni/Cr/Si/Mg (Nicrosil) alloy and the other conductor 66 made of a Ni/Si (Nisil) alloy. In another exemplary embodiment, TC junction 68 is a Type K junction, with one conductor 64 made of a Ni/Cr (Chromel) alloy and the other conductor 66 made of a Ni/Mn/Al/Si (Alumel) alloy. The ends of conductors 64 and 66 overlap and directly contact one another to form TC junction 68. In this manner, the temperature sensor layer 62 provides an electrically conductive layer including conductors 64 and 66 which are electrically insulated from substrate 52.

In the pre-cured composition of temperature sensor layer 62, the conductive metal particles, such as particles of Ni/Cr/Si/Mg and Ni/Si alloys, or Ni/Cr and Ni/Mn/Al/Si alloys, form the bulk of the final layer. These metal particles may have a particle size of as little as 1 micron, 3 microns, 5 microns, or as great as 7 microns, 9 microns, or 12 microns, or may be within any size range defined between any two of the foregoing values.

The polymeric resin provides a binder or carrier matrix for the conductive metal particles, and also provides adhesion of the composition to the underlying insulating layer 60 prior to the heat cure step in which the polymeric resin is removed. The organic carrier liquid provides a removable carrier medium to facilitate application of temperature sensor layer 62 prior to heat cure, and is removed upon heat cure. The pre-cured composition of temperature sensor layer 62 may also include other additives, such as surfactants, stabilizers, dispersants, as well as one or more thixotropic agents such as hydrogenated castor oil, for example, to increase the viscosity as necessary in order to form a paste.

The polymer resin may be an epoxy resin, ethyl cellulose, ethyl hydroxyethyl cellulose, wood rosin, phenolic resins, polymethacrylates of lower alcohols, or mixtures of the foregoing.

Suitable organic carrier liquids or solvents include those listed above in connection with the composition of insulation layer 60, or mixtures of the foregoing.

In the composition of circuit layer 62, the metallic particles are typically present in an amount from as little as 45 wt. %, 50 wt. % or 55 wt. % to as great as 70 wt. %, 75 wt. % or 80 wt. % of the total composition, or may be present in an amount within any range defined between any two of the foregoing values. The glass phase or other metal oxide particles may be absent from the composition or, if included, may be present in an amount of as little as 1 wt. %, 3 wt. % or 5 wt. % or as great as 7 wt. %, 9 et. % or 10 wt. % of the total composition, or may be present in an amount within any range defined between any two of the foregoing values. Typically, the solvent will comprise the primary component of the balance of the composition.

Similar to insulating layer 60, the temperature sensor layer 62 composition may be applied via a screen printing process through a screen or stencil directly onto insulation layer 60, optionally followed by an initial drying step, either at ambient or elevated temperature, in which some of the volatile components of the composition are evaporated. In a subsequent step after initial application followed by optional drying, temperature sensor layer 62 may be heat cured in a furnace, such as a belt furnace, by heating temperature sensor layer 62 to a desired elevated curing temperature to drive off any remaining volatile components, leaving the final layer in cured, solid form. The curing temperature will typically be greater than 800° C., and below the melting point of the substrate.

Total thickness for circuit layer 62 following successive film builds by the foregoing additive deposition thick film techniques may be as thin as 3 microns, 5 microns, or 10 microns, or as thick as 20 microns, 50 microns, or 100 microns, or may have a thickness within any range defined between any two of the foregoing values.

In one embodiment, temperature sensor layer 62 may be deposited in a manner in which a first layer, including first conductor 64, is deposited initially and then heat cured, followed by depositing a second layer, including second conductor 66, which is then subsequently heat cured.

Alternatively, in another embodiment, temperature sensor layer 62 may be deposited in a manner in which a first layer, including first conductor 64, is deposited initially, followed by depositing a second layer, including second conductor 66, following by “co-firing” the layers, namely, curing both layers in a single heat curing step. In either case, although the material of each of the first and second layers is both deposited onto insulating layer 60, the material of the second layer is at least in part deposited over a portion of the material of the underlying first layer in an overlapping manner to form the TC junction 68. One advantage of the approach described above in which the first and second layers are applied and then “co-fired” is that the metals or metal alloys of the layers partially diffuse into each other during the heat cure process to form a very thin diffusion zone or alloyed junction 65, shown in FIG. 3B, in which the metals or metal alloys are intimately diffused into one another to form a robust, durable thermocouple junction which is resistant to very high temperatures.

Conductors 64 and 66 each generally include distal portions 64a and 66a and proximal portions 64b and 66b, respectively, with distal portions 64a and 66a overlapped and in direct contact with one another to form the TC junction 68 as described above. Distal portions 64a and 66a will, in use of the temperature sensor 50, be exposed to an operational environment for temperature sensing, while proximal portions 64b and 66b will not be exposed to such environment but rather are electrically connected via a suitable connector arrangement 70, illustrated in dashed lines in FIG. 2. Advantageously, due to the fact that proximal end 56 of substrate is not exposed to the operational environment, such as a very high temperature environment, connector arrangement 70 may be a standard, readily available connector arrangement which is adapted for use at ambient temperatures or temperatures less than 150° C., for example. Connector arrangement 70 may include connectors 72 welded or otherwise secured to pads 74 at the proximal portions 64b and 66b of conductors 64 and 66, with connectors 72 further connected to leads 76 which are in turn connected to suitable temperature sensing hardware or software (not shown).

In this manner, a continuous conductive circuit or trace is formed, which extends from the TC junction 68 at the distal end 54 of substrate 52 to the proximal portions 64b and 66b of conductors 64 and 66 at the opposing proximal end 56 of substrate 52. Advantageously, the deposition of the foregoing materials via thick film techniques allows the use of different materials for forming conductors 64 and 66, yet obviates the need for separate connections which are formed via metallic solder re-flow techniques or welding, for example, which are more cumbersome to manufacture.

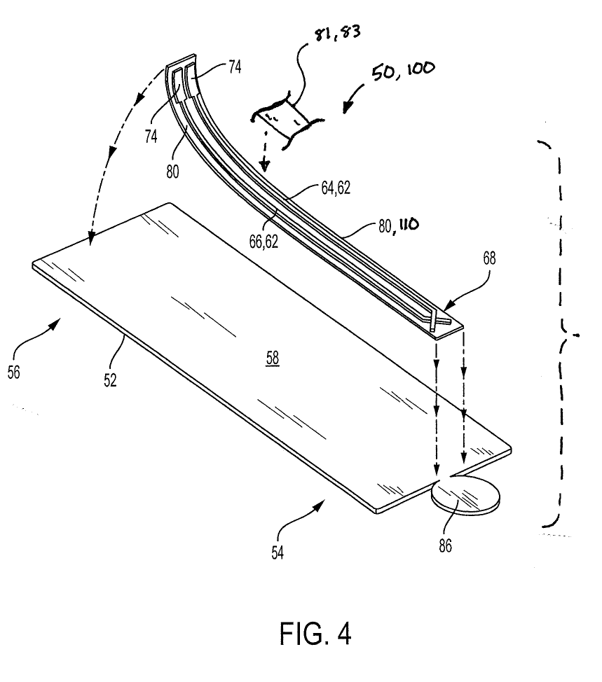

Referring to FIG. 4, in another embodiment, insulating layer 60 may be provided in the form of a ceramic tape 80, having a first side onto which temperature sensor layer 62 may be deposited via the thick film techniques described above while ceramic tape 80 is in a partially cured or “green” state. In the partially cured or “green” state, as shown in FIG. 4, ceramic tape 80 is flexible and may be applied with its opposite, second side directly onto the deposition surface 58 of substrate 52. Then, the construct including substrate 52 and ceramic tape 80 with its temperature sensor layer 64 is heat cured at a temperature greater than 800° C., for example, to sinter ceramic tape 80 and heat cure temperature sensor layer 64, which results in ceramic tape 80 being permanently adhered to substrate 52. In one embodiment, the foregoing construct may be placed between a pair of heated platens and subjected to heat and pressure to laminate ceramic tape 80 to substrate 52, such as 70° C. at 3000 psi, for example. In another embodiment, the lamination may occur via a hot isostatic pressing (“HlPing”) process, for example at elevated temperature and pressure.

Still referring to FIG. 4, in a still further embodiment, the TC type temperature sensor 50 may lack the substrate 52 and may take the form of a freestanding body include only the ceramic tape 80 and temperature sensor layer 62. In this manner, in FIG. 4 the presence (or lack) of the substrate 52 is illustrated by the combination bracket shown in dashed lines. In the embodiment in which the temperature sensor lacks the substrate 52, the ceramic tape 80 may include a minimized amount, or may completely lack, any glass phase which would otherwise be used to adhere the ceramic tape 80 to the substrate 52. Further, in this embodiment, the temperature sensor layer 62 may be printed into an uncured or partially cured or partially sintered ceramic tape 80 when the tape 80 is in a “green” state, resulting in the temperature sensor layer 62 being at least partially, or fully, encapsulated, embedded, or buried within the tape 80. Optionally, a second layer of ceramic tape 81 may be placed or deposited over the first layer of ceramic tape 80 and the temperature sensor layer 62 to form a sandwich type structure, followed by co-firing all of the layers together. In another option, a protective layer in the form of a screen-printed high temperature glass 83 may be placed over the top of the assembly of ceramic tape 80 and temperature sensor layer 62.

Thus, after final firing of the tape 80 and temperature sensor layer 62, the resulting freestanding temperature sensor body may be a composite structure in which the components of the temperature sensor layer 62 are not directly exposed to, and are thus protected from, the external environment and are able to withstand higher temperatures, such as greater than 600° C., for example, as low as 800° C., 900° C., or 925° C. and as great as 975° C., 1000° C., or 1100° C., for example, or within any range defined between any pair of the foregoing values. Optionally, the freestanding TC type temperature sensor 50 may be housed within a low cost containment structure such as a metal sheath or tube.

Referring to FIG. 2, an optional cover layer 82 may be deposited over the area of thermocouple junction 68 in order to further protect thermocouple junction from direct exposure to harsh environmental conditions. Cover layer 82 may have the same composition as insulating layer 60 described above, and may be deposited according to the same thick film techniques. Alternatively, cover layer 82 may be a ceramic tape 80 which is placed over thermocouple junction and then sintered at high temperature as described above. In a still further embodiment, insulating layer 60, temperature sensor layer 62 and its conductors 64 and 66, and cover layer 82 may all be heat cured or “co-fired” together in a single step after thick film application.

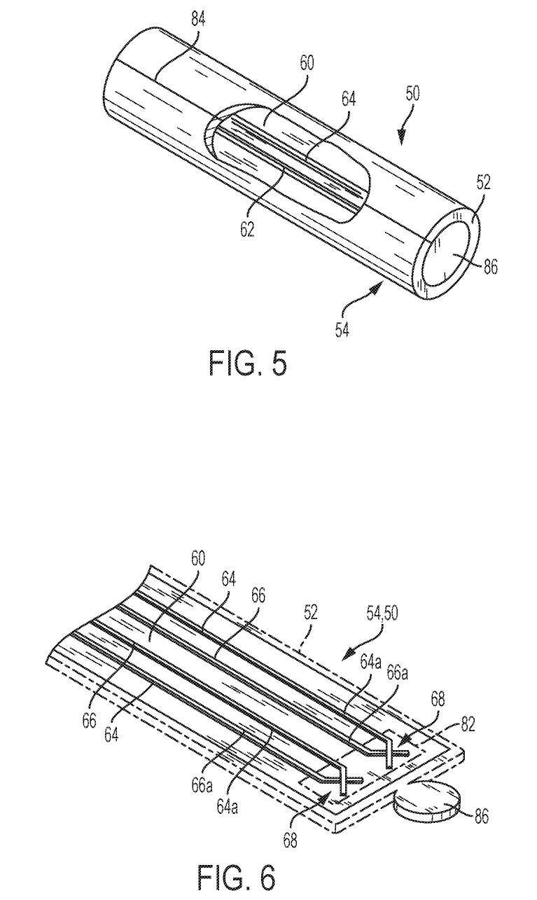

In FIGS. 2 and 4, sensor 50 is shown in a manufacturing configuration in which substrate 52 is flat in shape to promote the ability of depositing insulating layer 60 and temperature sensor layer 62 onto substrate 52 via the thick film techniques described above. Referring to FIG. 5, after insulating layer 60 and temperature sensor layer 62 have been deposited onto substrate 52 and heat cured, substrate 52 may be roll formed into a use configuration in which sensor 50 has a tube shape in the manner generally exemplified by the corresponding arrows in FIG. 2. Other, alternative cross-sectional shapes of substrate in the use configuration are described below. In the use configuration, insulating layer 60 and temperature sensor layer 62 are disposed within the interior of the sensor 50 to minimize exposure to harsh environmental conditions. Following roll forming into the tube shape, a suitable weld may be employed along the axially-extending abutment seam 84 along the opposite sides of substrate 52 to secure same to one another.

Referring to FIGS. 2 and 5, substrate 52 may also include an end cap 86 which may be bent or otherwise deformed in the manner generally exemplified by the corresponding arrows in FIG. 2 into the position shown in FIG. 5, in which same is abutted against, or received into, the distal end 54 of sensor 50 such that the overall tube shape of sensor 50 protects conductors 64 and 66 and/or other components of the sensor 50 from damage.

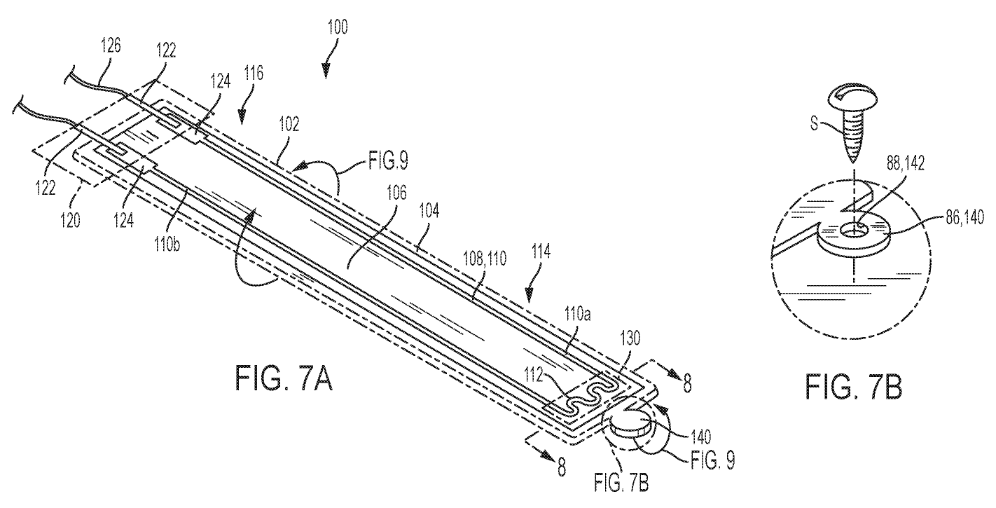

However, in other embodiments, sensor 50 may be used in a configuration in which substrate 52 remains in a flat shape wherein, as shown in FIG. 7B, end cap 86 may be alternatively configured as a fastener attachment point including an aperture 88 for receipt of a fastener such as a screw “S” for securing sensor 50 to a suitable use substrate such as a wall or housing, for example. Sensor 50 may include several such fastener attachment points around its perimeter as may be needed.

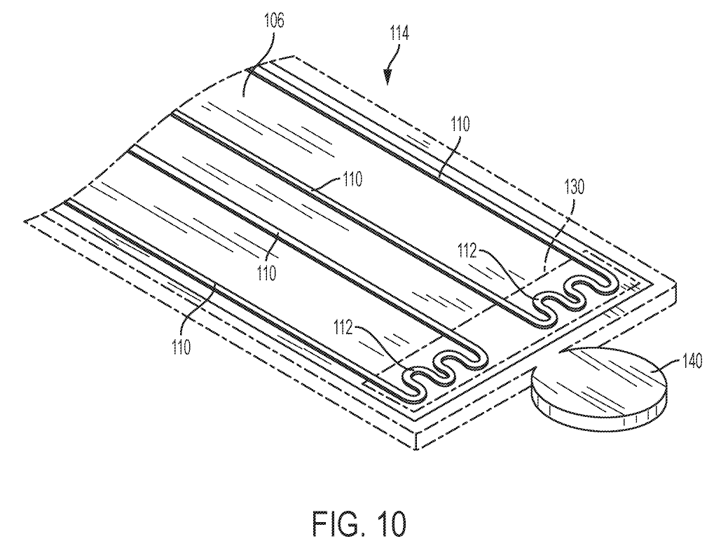

In use, as described in further detail below with respect to FIG. 10, distal end 54 of sensor 50 is exposed to an operational environment for temperature sensing, while proximal end 56 of sensor 50 is not exposed to the operational environment but rather is used to form an electrical connection to suitable temperature sensor hardware or software.

As shown in FIG. 6, in another embodiment, sensor 50 may include multiple conductor pairs 64, 66 forming multiple respective TC junctions 68. Advantageously, multiple conductors, such as a pair, 3, 4, 5, or 10 or more, for example, may be deposited simultaneously onto insulating layer 60 of substrate 54 via the thick film deposition techniques described above, with the result that multiple respective TC junctions 68 may be present for operational redundancy in the event of a failure of any one TC junction 68, thereby increasing the operational service life of sensor 50.

II. Resistance Temperature Detector (RTD) Type Sensors

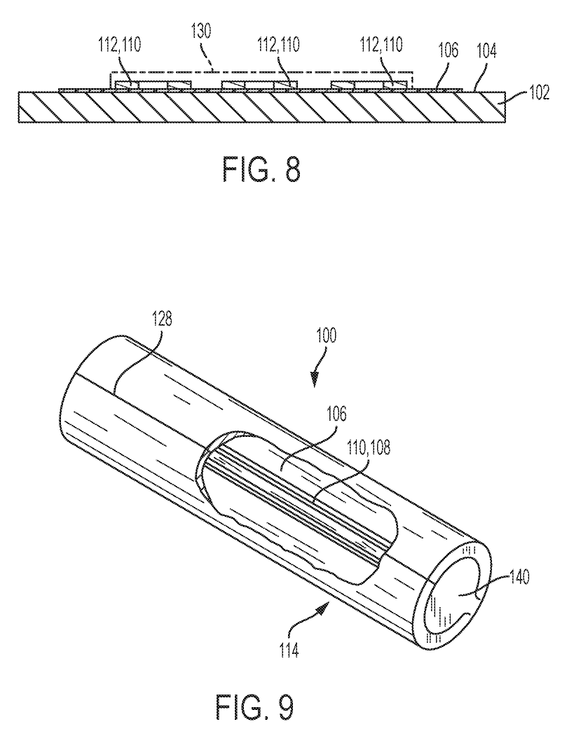

Referring to FIGS. 7A and 8, an RTD type temperature sensor 100 is shown, which includes a substrate 102 that may be formed of the same or similar materials as that of TC type temperature sensor 50 described above, and includes an exposed deposition surface 104 on which a temperature sensor structure is directly deposited via a thick film deposition method.

A dielectric or electrically insulting layer 106 is deposited directly on deposition surface 104 of substrate via a thick film technique such as screen printing, in substantially the same manner as described above in connection with TC type temperature sensor 50, and insulating layer 106 has an identical function as that of insulating layer 60 of TC type temperature sensor 50. In another embodiment, insulating layer 102 may be in form of a ceramic tape, as also described above.

Thereafter, a temperature sensor layer 108 may be deposited directly onto the insulating layer 106 via similar film thick film techniques as described above. The temperature sensor layer 108 may be provided in the form of a viscous liquid or paste which generally includes conductive metal particles, at least one polymeric resin, and at least one organic carrier liquid or solvent. The composition of temperature sensor layer 108 may also include a glass phase or metal oxide particles to promote adhesion of temperature sensor layer to the underlining insulating layer 106.

In this embodiment, temperature sensor layer 108 includes a temperature sensor element in the form of a single conductor filament 110 which is deposited onto insulating layer 106 in the form of a serpentine pattern or other tortious path or trace including a number of segments 112 in order to maximize the extent to which conductor filament 110 is exposed to an operational environment for temperature sensing. Filament 110 is a pure metal such as platinum, nickel, or copper, for example. In one embodiment, the purity of the metal used for filament may be at least 99.99 wt. % (4N), 99.999 wt. % (5N), 99.9999 (6N).

In another embodiment, insulating layer 106 may be provided in the form of a ceramic tape as described above with reference to FIG. 4, onto which temperature sensor layer 108 may be deposited via thick film techniques while the ceramic tape is in a partially cured or “green” state, followed by laminating the ceramic tape to substrate 102 as described above. In this embodiment, temperature sensor layer 110 may be provided in the form of a resinate solution including an organometallic compound which is dissolved in an organic solvent that is printable onto the ceramic tape and then fired to form a metallic film. Advantageously, because the ceramic tape typically has a porous structure on a microscale level, excellent print definition may be achieved using an organometallic resinate solution because the organometallic components remain in solution and follow the solution in a uniform and controlled manner through the microporosity of the ceramic tape, thereby approximating print definitions achievable by much more expensive thin film techniques such as photolithography.

In a still further embodiment, with further reference to FIG. 4, the RTD type temperature sensor 100 may lack substrate 52 and may take the form of a freestanding body include only the ceramic tape 80 and a temperature sensor layer 110. In this manner, the presence (or lack) of a substrate is illustrated by the combination bracket shown in dashed lines in FIG. 4. In the embodiment in which the RTD temperature sensor 100 lacks a substrate, the ceramic tape 80 may include a minimized amount, or may completely lack, any glass phase which would otherwise be used to adhere the ceramic tape 80 to a substrate. Further, in this embodiment, the temperature sensor layer 110 may be printed into an uncured or partially cured or partially sintered ceramic tape 80 when the tape 80 is in a “green” state, resulting in the temperature sensor layer 110 being at least partially, or fully, encapsulated, embedded or buried within the tape 80. Optionally, a second layer of ceramic tape 81 may be placed or deposited over the first layer of ceramic tape 80 and the temperature sensor layer 110 to form a sandwich type structure, followed by co-firing all of the layers together. In another option, a protective layer in the form of a screen-printed high temperature glass 83 may be placed over the top of the assembly of ceramic tape 80 and temperature sensor layer 110.

Thus, after final firing of the tape 80 and temperature sensor layer 110, the resulting freestanding temperature sensor body may be a composite structure in which the components of the temperature sensor layer 110 are not directly exposed to, and are thus protected from, the external environment and are able to withstand higher temperatures, such as greater than 600° C., for example, as low as 800° C., 900° C., or 925° C. and as great as 975° C.,1000° C., or 1100° C., for example, or within any range defined between any pair of the foregoing values. Optionally, the freestanding RTD temperature sensor 100 may be housed within a low cost containment structure such as a metal sheath or tube.

Filament 110 generally includes a distal portion 110a applied to distal end 114 of substrate 102, and a proximal portion 110b applied to proximal end 116 of substrate 102, with distal portion 110a having a serpentine pattern as described above, including a plurality of segments 112. Distal portion 110a will, in use of the temperature sensor 100, be exposed to an operational environment for temperature sensing, while proximal portion 110b will not be exposed to such environment but rather is electrically connected via a suitable connector arrangement 120, illustrated in dashed lines in FIG. 7A. Advantageously, due to the fact that proximal end 116 of substrate 102 is not exposed to the operational environment, such as a very high temperature environment, connector arrangement 120 may be a standard, readily available connector arrangement which is adapted for use at ambient temperatures or temperatures less than 150° C., for example. Connector arrangement 120 may include connectors 122 welded or otherwise secured to pads 124 at the proximal portion 110b of filament 110, with connectors 122 further connected to leads 126 which are in turn connected to suitable temperature sensing hardware or software (not shown).

In one embodiment, only the distal portion 110a of filament 110 is formed of the applicable material which provides the RTD sensor function of filament 110, such as platinum, nickel, or copper, wherein distal portion 110a may comprise as little as 1%, 5%, 10%, or 15% of the total axial length of filament 110 as deposited onto insulating layer 60. The remaining portion of filament 110, including proximal portion 110b, may be formed of a different electrically conductive metal or metal alloy, and may be deposited via thick film deposition steps which are separate from those by which distal portion 110a of filament 110 is deposited.

Advantageously, according to this arrangement, distal portion 110a of filament 110, which provides the RTD sensor function, may be made of a relatively expensive metal or metal alloy, with the amount of such material conserved as opposed to the remaining material of proximal portion 110b of filament 110, which may be made of a relatively less expensive metal or metal alloy. For example, in one embodiment, the distal portion 110a of filament 110 may be deposited onto insulating layer 106, followed by heat curing, followed by depositing the proximal portion 110b of filament 110 on insulating layer 106 with at least a portion of the proximal portion 110b of filament 110 in an overlapped, electrically connected engagement with distal portion 110a, followed by heat curing in the manner described above to form filament 110.

In this manner, a continuous conductive circuit or trace is formed, which extends from the distal portion 110a of filament 110 at a distal end 114 of substrate 102 to proximal portion 110b of filament 110 at an opposing proximal end 116 of substrate 102. The deposition of the foregoing materials via thick film techniques allows the use of different materials for forming the distal and proximal portions 110a and 110b of filament 110, yet obviates the need for separate connections which are formed via metallic solder re-flow techniques or welding, for example, which are more cumbersome to manufacture.

Optionally, a cover layer 130 may be deposited over the temperature sensing region of filament 110 in order to further protect filament 110 from direct exposure to harsh environmental conditions. Cover layer 130 may have the same composition as insulating layer 102 described above, and may be deposited according to the same thick film techniques. Alternatively, cover layer 130 may be a ceramic tape which is placed over filament 110 and then sintered at high temperature as described above. In a still further embodiment, insulating layer 102, temperature sensor layer 104 and its filament 110, and cover layer 130 may all be heat cured or “co-fired” together in a single step after thick film application.

In FIGS. 7A and 8, sensor 100 is shown in a manufacturing configuration in which substrate 102 is flat in shape to promote the ability of depositing insulating layer 106 and filament 110 of temperature sensor layer 108 onto substrate 102. Referring to FIG. 8, after the foregoing layers have been deposited onto substrate 102 and heat cured, substrate 102 may be roll formed into a use configuration in which sensor 100 has a tube shape in the manner generally exemplified by the corresponding arrows in FIG. 7A. In the use configuration, insulating layer 106 and temperature sensor layer 108 are disposed within the interior of the sensor 100 to minimize exposure to harsh environmental conditions. Following roll forming into the tube shape, a suitable weld may be employed along the axially-extending abutment seam 128 along the opposite sides of substrate 102 to secure same to one another.

Referring to FIGS. 7A and 9, substrate 102 may also include an end cap 140 which may be bent or otherwise deformed in the manner generally exemplified by the corresponding arrows in FIG. 7A into the position shown in FIG. 9, in which same is abutted against, or received into, the distal end 114 of sensor 100 such that the overall tube shape of sensor 100 protects filament 110 and/or other components of the sensor 100 from damage.

However, in other embodiments, sensor 100 may be used in a configuration in which substrate 102 remains in a flat shape wherein, as shown in FIG. 7B, end cap 140 may be alternatively configured as a fastener attachment point including an aperture 142 for receipt of a fastener 144, such as a screw “S”, for securing sensor 100 to a suitable use substrate such as a wall or housing, for example. Sensor 100 may include several such fastener attachment points around its perimeter as may be needed.

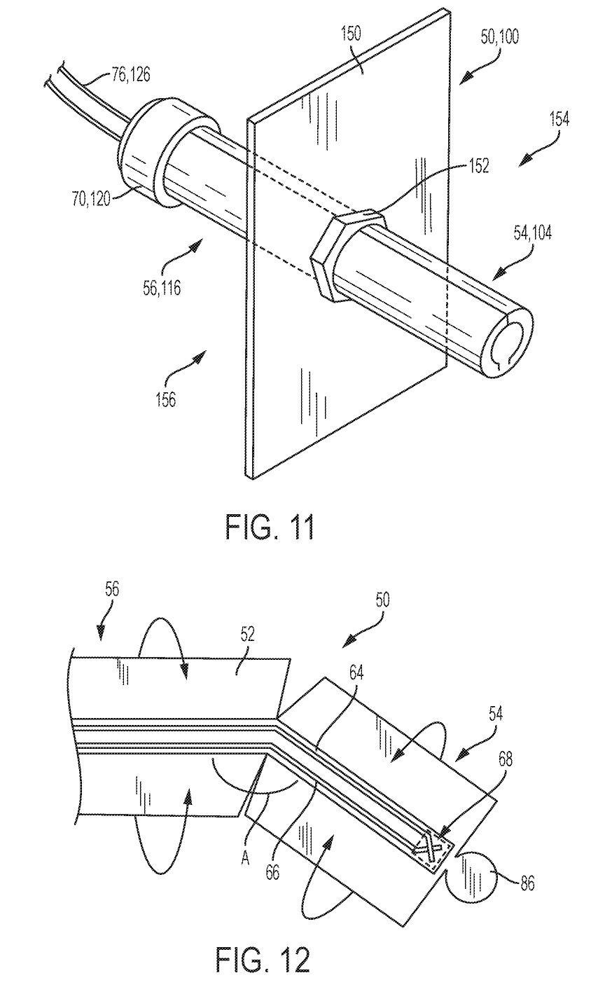

In use, as described in further detail below with respect to FIG. 11, distal end 114 of sensor 100 is exposed to an operational environment for temperature sensing, while proximal end 116 of sensor 100 is not exposed to the operational environment but rather is used to form an electrical connection to suitable temperature sensor hardware or software.

As shown in FIG. 10, in another embodiment, sensor 100 may include multiple filaments forming multiple respective RTD sensors. Advantageously, multiple filaments 110 may be deposited simultaneously onto insulating layer 106 of substrate 102 via the thick film deposition techniques described above, with the result that multiple respective RTD sensors may be present for operational redundancy in the event of a failure of any one of the filaments, thereby increasing the operational service life of sensor 100.

III. Sensor Use Configurations

Referring to FIG. 11, a sensor, which may be a TC type temperature sensor 50 or a RTD type temperature sensor 100, is shown in an exemplary operation configuration in which the sensor is mounted within a wall or housing 150 of a device using a suitable fitting 152. The device may be a wall of a reactor, an exhaust conduit, or any other device in which there is a need for temperature sensing. Distal end 54, 114 of the sensor 50, 100 extends through wall or housing 150 and is exposed to the operational temperature environment 154, while proximal end 56, 116 of sensor 50, 100 is disposed on the opposite side 156 of wall or housing 150 and is not exposed to the operational temperature environment 154, but rather is connected to suitable temperature sensor hardware or software via electrical connector 70, 120 and leads 76, 126. Advantageously, as described in detail above in connection with each sensor 50 and 100, the temperature sensing components and their respective conductors may be manufactured via thick film techniques to extend along the length of the sensor substrate to minimize the number of electrical connections present, thereby easing manufacture and decreasing points of potential operational failure. Further, because electrical connector 70, 120 is disposed on the opposite side 156 of wall or housing 150 not exposed to the operational temperature environment 154, electrical connector 70, 120 may be a relatively inexpensive, readily available connector which is not designed for use at high temperatures.

Referring to FIG. 12, a further embodiment is shown in connection with TC type sensor 50, though the same configuration could also be used with RTD type sensor 100. The distal end 54 and proximal end 56 of substrate 52 may be formed into use configurations separately from one another, with a bend between the two ends. In this manner, the distal end 54 and proximal end 56 are not co-axial but rather an angle “A” is formed between the ends, which may be advantageous in certain use environments in which spatial constraints are present. Angle “A” will typically be obtuse as illustrated, though may also be 90°, or even acute. Typically, the printed thin film layers are printed onto the flat or planar substrate in which the distal end 54 and proximal end 56 are disposed at an angle with respect to one another, followed by separately forming the side regions of one or both of the distal and proximal ends into a tubular form as described above and illustrated by the arrows in FIG. 12.

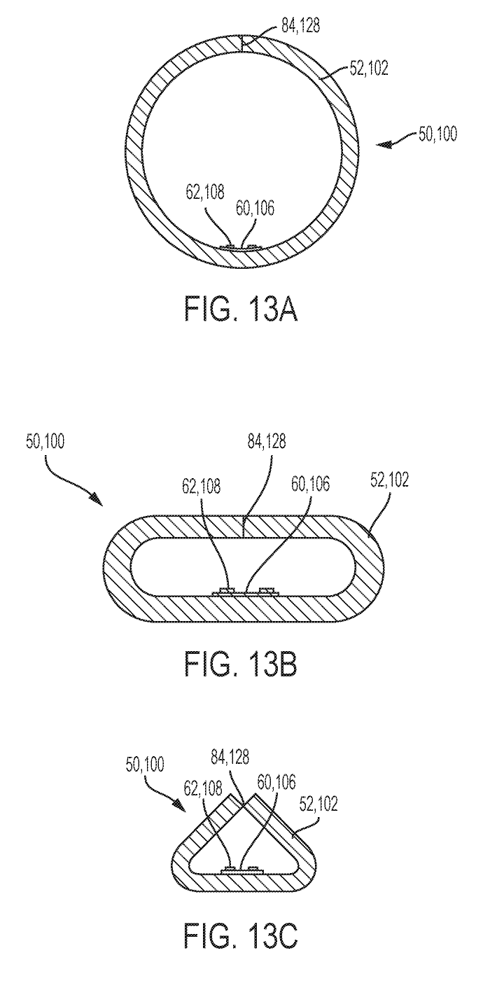

Referring to FIGS. 13A-13C, substrates 52 and 102 of temperature sensors 50 and 100 may be formed into various cross-sectional figurations. First, referring to FIG. 13A, as described above, substrates 52 and 102 of temperature sensors 50 and 100 may be roll formed into a circular cross-sectional configuration, with the substrate sides secured to one another by welding long seam 84, 128 in the manner described above with respect to FIGS. 5 and 9. In this configuration, the thick film layer set, including the insulating layers 60 and 106 and temperature sensor layers 62 and 108, may be somewhat deformed by placing the layers in compression during the roll-forming operation. However, the overall width dimension of the thick film layer set may be minimized relative to the width of the substrate, resulting in the diameter of the formed sensor 50, 100 being sufficiently large to minimize the extent of deformation of the thick film layer set.

Referring to FIG. 13B, substrates 52 and 102 of temperature sensors 50 and 100 may be formed into an ovoid cross-sectional configuration, with the substrate sides secured to one another by welding long seam 84, 128. This configuration may be advantageous in that the applied thick film layer set, including the insulating layers 60 and 106 and temperature sensor layers 62 and 108, remain disposed on a planar portion of substrate 52 or 102 which is not deformed to form the final cross-sectional configuration.

Referring to FIG. 13C, substrates 52 and 102 of temperature sensors 50 and 100 may be formed into a triangular cross-sectional configuration, with the substrate sides secured to one another by welding long seam 84, 128. Similar to the configuration of FIG. 13B, this configuration may be advantageous in that the applied thick film layer set, including the insulating layers 60 and 106 and temperature sensor layers 62 and 108, remain disposed on a planar portion of substrate 52 or 102 which is not deformed to form the final cross-sectional configuration.

In still further embodiments, with reference to FIGS. 2 and 7A, substrates 52 and 102 of temperature sensors 50 and 100 may include distal ends 54 and 114 which extend beyond their respective temperature sensor elements, namely, thermocouple junction 68 and filament 110, allowing such ends to be mechanically crimped following the forming operation to thereby provide a closed end to protect the interior of the sensor.

While this disclosure has been described as having exemplary designs, the present disclosure can be further modified within the spirit and scope of this disclosure. This application is therefore intended to cover any variations, uses, or adaptations of the disclosure using its general principles. Further, this application is intended to cover such departures from the present disclosure as come within known or customary practice in the art to which this disclosure pertains and which fall within the limits of the appended claims.

What is claimed is:

1. A temperature sensor, comprising:
an elongate metallic substrate having a deposition surface and opposite distal and proximal ends, said distal end adapted to be exposed to a high temperature environment;
an insulating layer deposited on at least a portion of said deposition surface of said substrate;
a temperature sensor layer deposited on said insulating layer, said temperature sensor layer comprising:
a temperature sensor element at said distal end of said substrate, said temperature sensor element in the form of a thermocouple junction including first and second conductors made of differing metallic materials, respective portions of said first and second conductors directly connected to one another; and
a plurality of elongate conductors extending from said temperature sensor element to said proximal end of said substrate.

2. The temperature sensor of claim 1, wherein said thermocouple junction is an N-type junction in which said first conductor is made of a Ni/Cr/Si/Mg alloy and said second conductor is made of a Ni/Si alloy.

3. The temperature sensor of claim 1, wherein said thermocouple junction is a K-type junction in which said first conductor is made of a Ni/Cr alloy and said second conductor is made of a Ni/Mn/Al/Si alloy.

4. The temperature sensor of claim 1, wherein insulating layer is a ceramic material.

5. The temperature sensor of claim 1, wherein said substrate is formed into a tube with said insulating layer and said temperature sensor layer disposed on an interior of said tube.

6. The temperature sensor of claim 1, wherein said insulating layer has a thickness of between 10 and 50 microns.

7. The temperature sensor of claim 1, wherein said temperature sensor layer has a thickness of between 10 and 50 microns.

8. The temperature sensor of claim 1, further comprising an electrical connector electrically connected to said elongate conductors at said proximal end of said substrate.

9. The temperature sensor of claim 1, further comprising a protective layer, said protective layer deposited over at least said temperature sensor element of said temperature sensor layer.

10. A method of manufacturing a temperature sensor, comprising the following steps:
providing an elongate substrate having distal and proximal ends;
applying an insulating material onto a surface of the substrate via a thick film deposition process;
heat curing the insulating material to form an insulating layer;
applying a first metallic composition;
applying a second metallic composition with at least a portion of the second metallic composition applied over and in contact with the first metallic composition; and
heat curing the first and second metallic compositions simultaneously to form first and second conductors with at least a portion of the second conductor directly contacting the first conductor to form a thermocouple junction.

11. The method of claim 10, wherein said applying steps are each performed via a thick film deposition process including screen printing of a paste of particles in a suspension.

12. The method of claim 10, further comprising the additional step, following said attaching step, of:
forming the substrate into a tube shape having a cross-sectional shape of one of circular, ovoid, or triangular to at least partially surround the insulating and circuit layers.

13. The method of claim 10, wherein the thermocouple junction is an N-type junction in which the first metallic composition is made of a Ni/Cr/Si/Mg alloy and the second metallic composition is made of a Ni/Si alloy.

14. The method of claim 10, wherein the thermocouple junction is a K-type junction in which the first metallic composition is made of a Ni/Cr alloy and the second metallic composition is made of a Ni/Mn/Al/Si alloy.

15. The method of claim 10, wherein the insulating layer is applied and cured to a thickness of between 10 and 50 microns.

16. The method of claim 10, wherein the first and second metallic compositions are each applied and cured to a thickness of between 10 and 50 microns.

17. A method of manufacturing a temperature sensor, comprising the following steps:
providing a ceramic tape having opposite first and second sides;
applying a first metallic composition to the first side of the ceramic tape via a thick film deposition process;
applying a second metallic composition to the first side of the ceramic tape via a thick film deposition process with at least a portion of the second metallic composition applied over and in contact with the first metallic composition; and
heat curing the ceramic tape and the temperature sensor material to heat cure the first and second metallic compositions simultaneously to form first and second conductors with at least a portion of the second conductor directly contacting the first conductor to form a thermocouple junction.

18. The method of claim 17, wherein the thermocouple junction is one of:
an N-type junction in which the first metallic composition is made of a Ni/Cr/Si/Mg alloy and the second metallic composition is made of a Ni/Si alloy; and
a K-type junction in which the first metallic composition is made of a Ni/Cr alloy and the second metallic composition is made of a Ni/Mn/Al/Si alloy.

19. The method of claim 17, wherein the first and second metallic compositions are each applied and cured to a thickness of between 10 and 50 microns.

20. The method of claim 17, further including, after said second applying step and prior to said heat curing step, the additional step of applying the ceramic tape to a substrate, wherein said heat curing step simultaneously heat cures the ceramic tape and adheres the ceramic tape to the substrate.
